(19) United States
(12) Patent Application Publication
(10) Pub. No.: US 2009/0152600 A1
(43) Pub. Date: Jun. 18, 2009

(54) PROCESS FOR REMOVING ION-IMPLANTED PHOTORESIST

(75) Inventors: Srinivasa Raghavan, Allen, TX (US); Murlidhar Bashyam, Richardson, TX (US); Mike Tucker, McKinney, TX (US); Kalyan Cherukuri, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/250,628

(22) Filed: Oct. 14, 2008

Related U.S. Application Data
(60) Provisional application No. 60/981,703, filed on Oct. 22, 2007.

(51) Int. Cl. H01L 29/78; H01L 21/265

(52) U.S. Cl. 257/288; 438/514; 257/E21.334; 257/E29.255

(57) ABSTRACT

A method of manufacturing an IC that comprises fabricating a semiconductor device. Fabricating the device includes depositing a photoresist layer on a substrate surface and implanting one or more dopant species through openings in the photoresist layer into the substrate, and, into the photoresist layer, thereby forming an implanted photoresist layer. Fabricating the device also includes removing the implanted photoresist layer. Removing the implanted photoresist layer includes exposing the implanted photoresist layer to a mixture that includes sulfuric acid, hydrogen peroxide and ozone. The mixture is at a temperature of at least about 130°.

### CROSS-REFERENCE TO PROVISIONAL APPLICATION

This application claims the benefit of U.S. Provisional Application Ser. No. 60/981,703, to Srinivasa Raghavan, et al. on Oct. 22, 2007, entitled “SULFURIC ACID, HYDROGEN PEROXIDE AND OZONE MIXTURE (SPOM) FOR STRIPPING OF IMPLANTED PHOTORESIST,” commonly assigned with the invention and incorporated herein by reference.

### TECHNICAL FIELD

The invention is directed, in general, to integrated circuits (ICs), and more specifically, to the manufacture of ICs requiring the removal of an ion-implanted photoresist.

### BACKGROUND

The manufacture of semiconductor devices often includes forming a photoresist layer on a substrate, and implanting ions through openings in the photoresist layer into the substrate to form doped regions. When the photoresist layer is subject to the ion implantation process, an outer portion of the photoresist is converted into an implant crust.

Typically, a plasma ash process is used to remove the implant crust. Once the implant crust is removed, the bulk of the remaining photoresist layer is often removed by conventional wet etch chemistries. Nevertheless, as increasingly smaller semiconductor devices are manufactured, there has been an increased frequency of defective devices produced by fabrication processes that include removing implanted photoresist layers by a plasma ash process.

Accordingly, what is needed is a method of manufacturing ICs by a method that includes removing an ion-implanted photoresist layers in a manner that permits high device yields.

### SUMMARY

One embodiment is a method of manufacturing an IC that comprises fabricating a semiconductor device. Fabricating the device includes depositing a photoresist layer on a substrate surface and implanting one or more dopant species through openings in the photoresist layer into the substrate. The dopant species are also implanted into the photoresist layer, thereby forming an implanted photoresist layer. Fabricating the device also includes removing the implanted photoresist layer. Removing the implanted photoresist layer includes exposing the implanted photoresist layer to a mixture that includes sulfuric acid, hydrogen peroxide and ozone. The mixture is at a temperature of at least about 130°.

Another embodiment is a method of manufacturing an IC that comprises fabricating the semiconductor device. Fabricating the device includes forming a gate structure on a substrate, and depositing a photoresist layer on the substrate, including the gate structure. An opening is formed in the photoresist layer so as to expose the gate structure and portions of the substrate in the vicinity of the gate structure. Dopant species are implanted through the openings into the substrate, and, into the photoresist layer, thereby forming an implanted photoresist layer. The implanted photoresist layer is removed by the above-described method.

Still another embodiment is an IC that comprises one or more semiconductor devices. Each device includes a gate structure on a substrate and one or more doped regions formed adjacent to the gate structure. At least one of the doped regions are formed by a process that includes depositing a photoresist layer on the substrate, implanting one or more dopant species through openings in the photoresist layer into the substrate, and into said photoresist layer, thereby forming an implanted photoresist layer, and removing the implanted photoresist layer by the above-described method.

### DRAWINGS

FIGS. 1 to 7 illustrate cross-section views of selected steps in example implementations of a method of fabricating an IC of the disclosure.

### DESCRIPTION

It was discovered that using a wet etchant mixture that includes sulfuric acid, hydrogen peroxide, and ozone, with the mixtures at an elevated temperature (e.g., at least about 130° C.), can efficiently remove an entire ion-implanted photoresist layer in a single step, including its ion-implanted crust. The single-step process disclosed herein eliminates the need for plasma ashing, which in turn, avoids the deposition of particles on the substrate as a byproduct of the plasma ash process.

It is surprising that the disclosed three-component combination of etchants works so well, because conventional wet etchant mixtures could not remove the outer implant crust in a reasonably short period (e.g., about 5 minutes or less). For instance, binary combinations of sulfuric acid and hydrogen peroxide, or, sulfuric acid and ozone, do not efficiently remove ion-implanted crusts formed when using implantation doses of 1E14 atom/cm² or higher. Consequently, these binary mixtures have only been used in conjunction with a plasma ash process. Since binary mixtures are not capable of removing the implant crust there is no reason to expect that a ternary mixture would be more effective.

Plasma ash processes, which are performed in a chamber, can cause the undesirable deposition of chamber-wall particles onto the substrate. E.g., quartz particles from quartz chamber walls of a plasma ash tool can be deposited through the openings in the photoresist layer directly onto the substrate. At least for larger device sizes (e.g., 180 nm and higher nodes), the presence of these chamber-wall particles have minimal effects on semiconductor device performance and therefore there has been no motive to try anything else besides the plasma ash process.

However, these particles can detrimentally affect the performance of smaller semiconductor devices. And, the severity of the detrimental effects from the deposited particle increases as the dimensions of the components in semiconductor devices become smaller (e.g., 90 nm and smaller nodes), resulting in lower than desired yields of semiconductor devices.

The detrimental effects associated with deposited particles are exacerbated by the use of even higher ion implantation doses, which is commonly done as part of forming smaller devices. Higher implantation doses can produce thicker ion-implant crusts that are more impermeable and resistant to the conventional wet etchants. Thicker crusts can also require more aggressive plasma ash processes for their removal. Because the semiconductor device's dimensions are smaller, there is increased risk that the plasma ash will inadvertently oxidize substantially portions of the substrate after removing the photoresist.

For small devices, the loss of a substrate thickness of as little as 1 Angstrom can substantially affect the performance characteristics of the device. E.g., the drive current at which a transistor device can operate at can be substantially changed. Moreover, those portions of the substrate not covered by the photoresist will be oxidized by the plasma ash to a greater extent than portions initially covered by the photoresist. This, in turn, can result in a non-uniform substrate surface when the oxidized substrate is removed, which in turn, can make it difficult to accurately define device features on the substrate using photolithographic procedures.

These considerations pointed to the need to find an alternative to plasma ashing and conventional wet etching processes as the industry moves towards producing device with ever-smaller dimensions.

It was recognized as part of this disclosure, that the conventional wet etchants are ineffective because they do not have sufficient oxidizing power (e.g., low concentrations of oxidizing free radicals, such as OH. radicals) to efficiently remove the implant crust. Typically, the photoresist is composed of one or more hydrocarbon-based polymers. The implant crust can be characterized as that portion of the photoresist layer that is depleted of hydrogen content, leaving behind a carbon-rich layer, as compared to the photoresist layer prior to ion implantation.

While not limiting the scope of the disclosure by theory, it is believed that ion-implantation drives lower molecular weight atoms of the photoresist (e.g., hydrogen atoms) to relatively deeper distances into the photoresist layer than high molecular weight atoms (e.g., carbon atoms) are driven. Consequently, the outer portions of the photoresist layer is chemically converted into a carbon-rich implant crust. It is further believed that the presence of relatively higher numbers of carbon-carbon bonds in the carbon-rich crust is what necessitates the use of the above-described three-component etchant mixture with its greater oxidizing power the remove the implant crust.

Some of the example embodiments disclosed herein feature the removal of an ion-implanted photoresist layer on a transistor semiconductor device substrate. However, the disclosed embodiments could be applied at any step in an IC fabrication scheme of other types of devices (e.g., capacitors, resistors) where it is important to remove a photoresist layer that has been ion-implanted.

One aspect of the invention is a method of manufacturing an IC that includes using the above-described three-component etchant mixture and elevated temperature as part of a photoresist removal process.

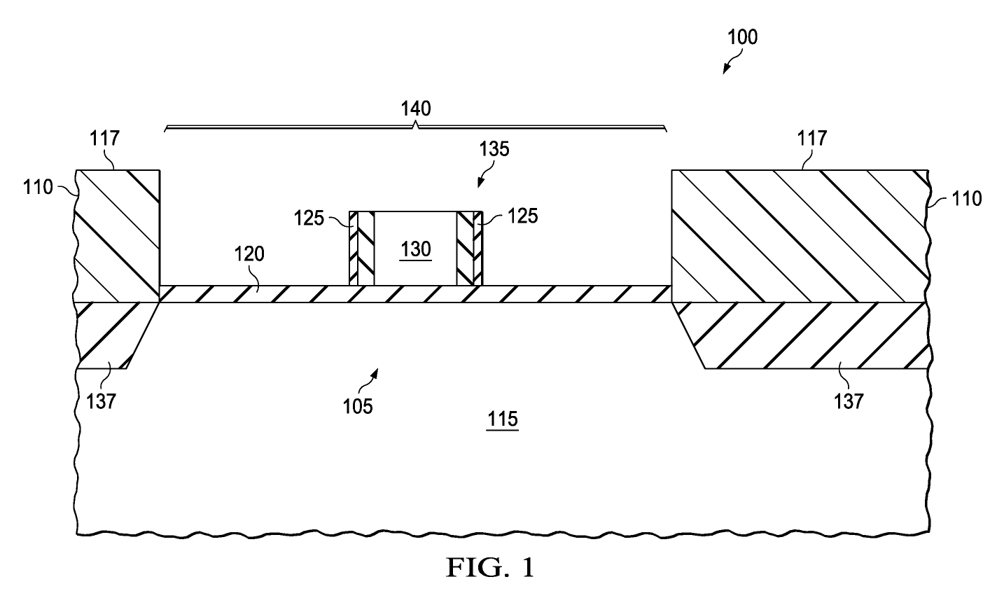

FIGS. 1-7 present cross-sectional views of an example IC 100 at different stages in it manufacture. The manufacture of the IC 100 comprises fabricating a semiconductor device 105. FIGS. 1-7 shows the IC 100 at selected stages in the fabrication of the semiconductor device 105.

FIG. 1 shows the device 105 after depositing a photoresist layer 110 on a substrate 115 surface 117. One skilled in the art would be familiar with the different types of hydrocarbon-based polymers that can be used as the photoresist layer 110. Non-limiting examples of photoresist material to form the layer 110 include 193 nm ultraviolet photoresists, such as hydrocarbon polymers that comprise polyacrylate, polymethylacrylate, or copolymers thereof. One skilled in the art would also be familiar with the types of materials that can be used as the substrate 115. E.g., in some cases, the substrate 115 is, or includes, a semiconductor wafer such as a silicon wafer substrate or a silicon-on-insulator wafer substrate. As further illustrated, in some embodiments, the substrate 115 can further include additional material layers formed thereon, such as a silicon oxide layer 120, silicon nitride layer 125 and polysilicon layer 130. At least some portion of these layers 115, 120, 125 can be part of a gate structure 135 of a metal on oxide (MOS) transistor device 105, such as an nMOS or pMOS transistor device 105. Insulating layers 137 (e.g. shallow trench isolation structures) on the substrate 115 can separate the device 105 from other active or passive devices of the IC.

FIG. 1 also shows the device 105 after forming one or more openings 140 in the photoresist layer 110. One skilled in the art would be familiar conventional photolithographic process to form openings 140 in photoresist materials. The opening 140 can be formed so as to expose portions of the substrate 115 in the vicinity of the device 105, including portions of the substrate 115 adjacent to the gate structure 135, in preparation for ion implantation.

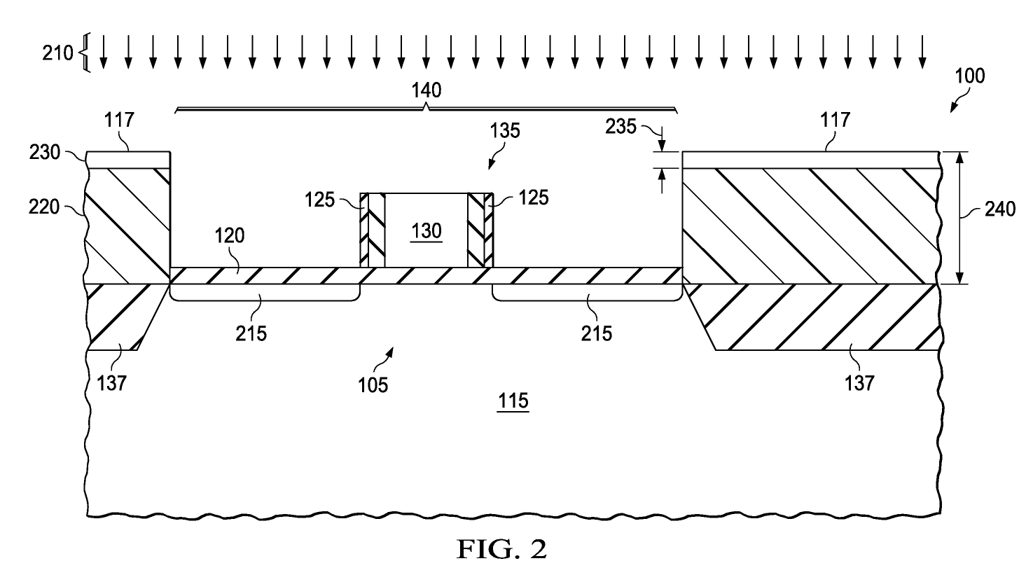

FIG. 2 shows the device 105 while implanting one or more dopant species 210 through the openings 140 in the photoresist layer 110 (FIG. 1) and into the substrate 115. The dopants 210 can be implanted as part of forming implanted regions 215 in the substrate 115 that are adjacent to the gate structure 135. The dopants 210 also get implanted into the photoresist layer 110 (FIG. 1), thereby forming an implanted photoresist layer 220. As discussed above, the implanted photoresist layer 220 can include an implant crust 230.

The implant crust 230 can be formed as an upper portion of photoresist layer 110. The crust 230 can form irrespective of the type of dopant species 210 that the photoresist layer 220 is implanted with. E.g., dopant species 210 can include one or more of: boron, carbon, nitrogen, phosphorus, fluorine, arsenic, or other well-known species used as dopants in semiconductor devices. The thickness 235 of the implanted crust 230 is a strong function of the dose of the ion implanted. The higher the ion implantation dose, the greater the thickness 235 of the implant crust 230. In some embodiments, the photoresist layer 110 has a total thickness 240 in a range of about 1000 to 5000 nm, and the outer implant crust 230 has a thickness 235 in a range of about 60 to 140 nm.

The thickness 235 of the crust 230 is also a weaker function of the type photoresist used, the ion implantation energy and the type of ion implant species. The higher the implantation dose and implant energy, the greater the degree of carbonization of the crust 230, and, consequently the greater level of oxidation power need to remove the crust 230. Example doses that cause crust formation are about 1E12 atom/cm² and higher. Example implantation energies that facilitate crust formation are about 10 keV and higher, and in some cases about 50 keV and higher. The implantation of high molecular weight dopant species 210 (e.g., arsenic), or, of high reactivity dopant species 210 (e.g., fluorine is highly reactive with the hydrocarbon polymers of the photoresist) increases the thickness 235 of the crust 230. The implantation dose, energy and type of ion implant species can cooperatively affect the extent of crust 230 formation. E.g., using about the same implantation energies, the implantation of a reactive dopant 210 such as fluorine at a dose of 6E14 atom/cm² can result in about the same thickness 235 of crust 230 being formed as implanting a less reactive dopant 210 such as boron implanted at 1E15 atom/cm².

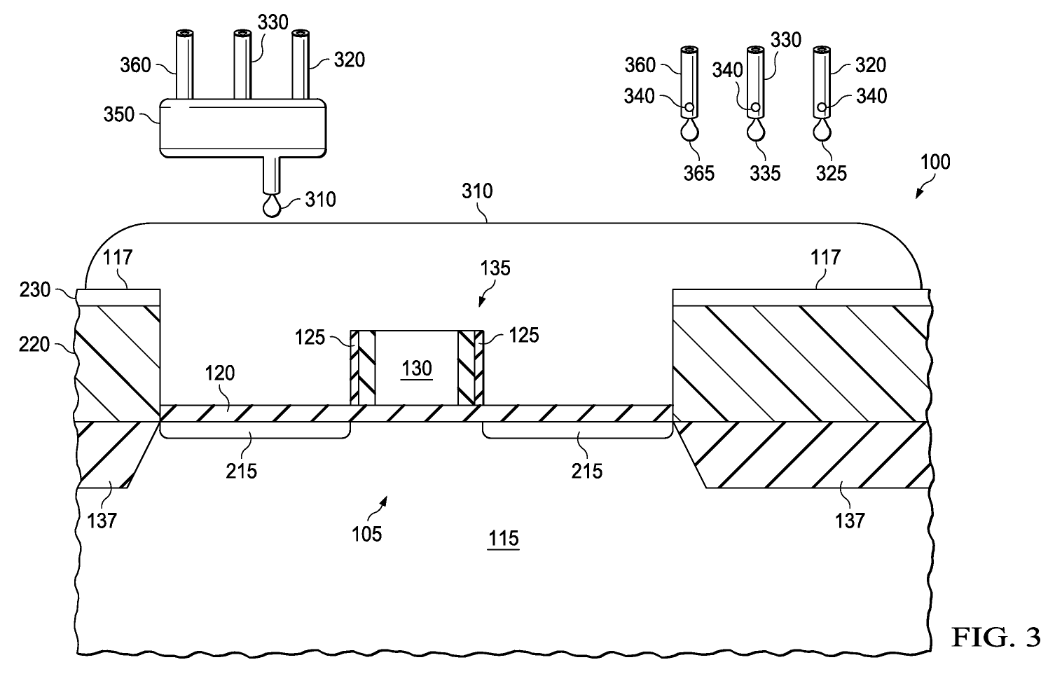

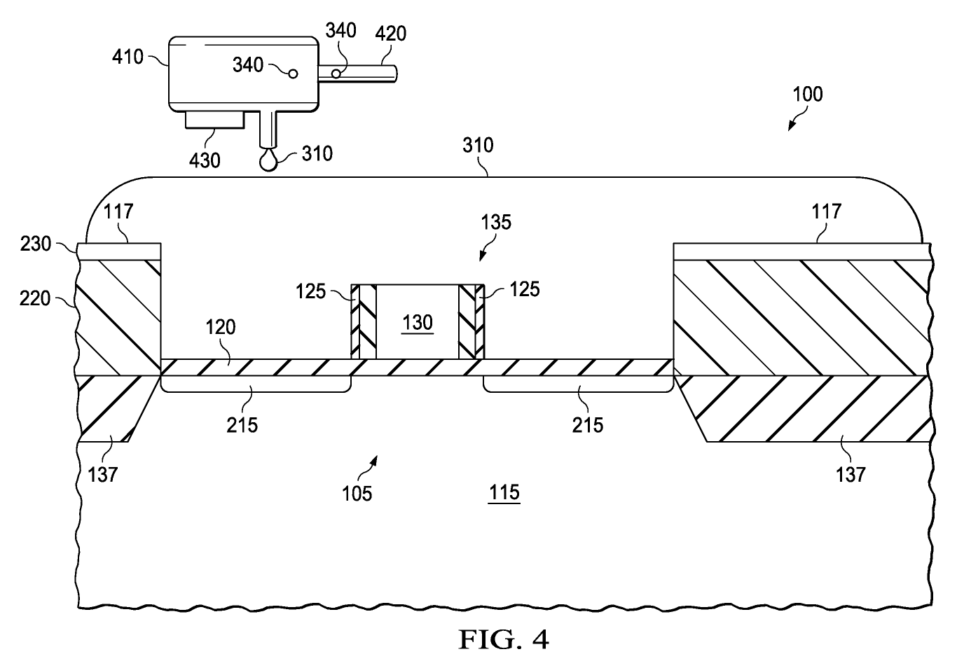

FIG. 3 shows the device 105 in one embodiment of removing the implanted photoresist layer 220. FIGS. 4-6 present alternative embodiments of removing the implanted photoresist layer 220. Removing the implanted photoresist layer 220 includes exposing the layer 220 to a wet-etch mixture 310 that includes sulfuric acid, hydrogen peroxide and ozone, with the wet-etch mixture 310 at a temperature of at least about 130° C.

In some preferred embodiments, the mixture's temperature is in a range of about 150 to 200° C. In some embodiments, it is desirable to maintain the temperature of the mixture 310 to be about 250° C. or less, because higher temperatures can promote the rapid loss of ozone from the mixture 310. In other cases, however, if ozone is added to the mixture shortly before it contacts the surface 117 (e.g., less than about 1 minute), higher temperatures can be used.

In some embodiments, the sulfuric acid and hydrogen peroxide are provided to the mixture as concentrated solutions. For instance, the sulfuric acid can be provides as an about 98 wt % w/w sulfuric acid solution (e.g., about 18 M H₂SO₄). The hydrogen peroxide can be provided as an about 30 wt % hydrogen peroxide solution (e.g., about 8.8 M H₂O₂). Other concentrations of sulfuric acid solution and hydrogen peroxide solution could be used, if desired. One skilled in the art would understand that concentrated solutions of sulfuric acid and hydrogen peroxide also contain balance water as well as trace amounts of other reactants or by-products of the processes used to prepare these compounds.

In some embodiments, the mixture 310 includes about 98 wt % sulfuric acid and about 30 wt % hydrogen peroxide provided in a ratio that ranges from about 65:35 to about 85:15, and that further includes ozone in a range of about 1 to 70 ppm by weight (e.g., about 1 to 50 mg O₃ per liter of the mixture). For example, as shown in FIG. 3, in some embodiments a first delivery tube 320 carries an about 600 ml/min flow of concentrated sulfuric acid 325 and a second delivery tube 330 carries an about 200 ml/min flow of concentrated hydrogen peroxide 335. One or both of sulfuric acid and hydrogen peroxide solutions 325, 335 can further include about 1 to 70 ppm of ozone dissolved therein. In some cases, to facilitate mixing, these flows can be combined on the substrate surface 117, while the substrate 115 is being spun. In some cases, to facilitate mixing, the flows of sulfuric acid and hydrogen peroxide can be combined in a mixing chamber 350 and then the mixture 310 delivered to the substrate 115 surface 117.

To be an effective means of removal, the wet-etch mixture 310 preferably removes the implanted photoresist layer 220 in less than about 5 minutes, and more preferably, less than about 2 to 3 minutes. To rapidly remove the ion-implanted photoresist layer 220, it is important to optimize the oxidizing power of the mixture 310 by presenting it directly to the substrate surface 117, (and photoresist layer 220 thereon) as soon as, or soon after, preparing the mixture 310. The longer the three components of the mixture 310 (sulfuric acid, hydrogen peroxide and ozone) are kept to together, the lower the concentration of reactive oxidative species (e.g., OH. radicals), generated from the three components. Consequently, the mixture 310 becomes less effective at removing the ion-implanted photoresist layer 220. Therefore, in some embodiments, it is advantageous to mix one or all of the components together at the substrate surface 117 (and photoresist layer 220), or, immediately before contacting the substrate surface 117.

In some embodiments, the wet-etch mixture 310 further includes water (e.g., de-ionized water) added within about 1 minute of the mixture 310 contacting the substrate surface 117. The water can be directly mixed with the three component mixture 310 of sulfuric acid, hydrogen peroxide and ozone, or, mixed with one of sulfuric acid or hydrogen peroxide, which are subsequently mixed together. One benefit in adding water to sulfuric acid or a mixture containing sulfuric acid is that a strong exothermic reaction occurs with a resultant large temperature increase. Provided that the mixture 310 with water added to it is not allowed to cool down, adding water can eliminate or reduce the need to have a separate heat source to heat one or all of the components of the mixture, or, the mixture itself. In some cases, however, it is still desirable to externally heat one or more of the components of the mixture 310 before the components are mixed. E.g., in some cases, the sulfuric acid is preheated to about 80° C. before being mixed with the other components of the mixture 310.

Another benefit in including water in the mixture 310 is that ozone can be dissolved in water and delivered to the other components (e.g., sulfuric acid and hydrogen peroxide) of the mixture 310 with the water. Ozone, however, is highly volatile and is not retained in water for very long. Moreover, ozone's volatility, and therefore escape from the mixture 310, is increased at higher temperatures. Therefore, in some cases, it is beneficial to add the ozone immediately before or while the mixture 310 contacts the implanted photoresist layer 220.

The beneficial features of including water, however, needs to be balanced with the undesirable excessive dilution of the three components of the mixture 310. That is, as more water is added to the mixture 310, the concentrations of sulfuric acid, hydrogen peroxide or ozone are decreased, and therefore, the oxidizing power of the mixture 310 is decreased.

For example, in some embodiments, the mixture 310 includes about 98 wt % sulfuric acid, about 30 wt % hydrogen peroxide, and water, provided in a ratio of that ranges from about 60:20:4 to about 80:30:8 and the mixture 310 further includes ozone in a range of about 1 to 70 ppm by weight. For instance, as shown in FIG. 3, in some embodiments, the first delivery tube 320 carries an about 600 ml/min flow of concentrated sulfuric acid 325, the second delivery tube 330 carries an about 200 ml/min flow of concentrated hydrogen peroxide, and a third delivery tube 360 carries an about 1 to 50 ml/min flow of water 365, the water 365 containing about 1 to 70 ppm ozone 340. In some cases the flow of water is adjusted so as to cause the desired elevated temperature of the mixture 310 (e.g., at least about 130° C.) to be attained on the substrate surface 117.

There are a number of different ways of that the mixture 310 can be formulated to facilitate removal of the implanted photoresist 220. As illustrated in FIG. 3, in some cases, the mixture 310 can be formulated directly on the substrate surface 117. For instance, a volume of sulfuric acid, a volume of hydrogen peroxide, and ozone dissolved in a volume of water can be simultaneously mixed together on the substrate surface 117. In other cases, the mixture 310 can be formulated in a mixing chamber 350 before being flowed on the substrate surface 117. For instance, the volumes of sulfuric acid, hydrogen peroxide, and ozone dissolved in water can be delivered via separate tubes 320, 330, 360 and simultaneously mixed together in a mixing chamber 350 before the mixture 310 is delivered to the substrate surface 117.

In other cases, such as shown in FIG. 4, sulfuric acid and hydrogen peroxide can be mixed together to form a binary mixture 410 and ozone 340 can be introduced as a gas into the binary mixture 410. E.g., a delivery tube 420 containing ozone 340 can be introduced into the binary mixture 410, preferably immediately prior to the ternary mixture's 310 delivery to the substrate surface 117. In such cases, the desired elevated temperature can be achieved by heating the binary mixture 410 with an external heat source 430 (e.g., an in-line heater).

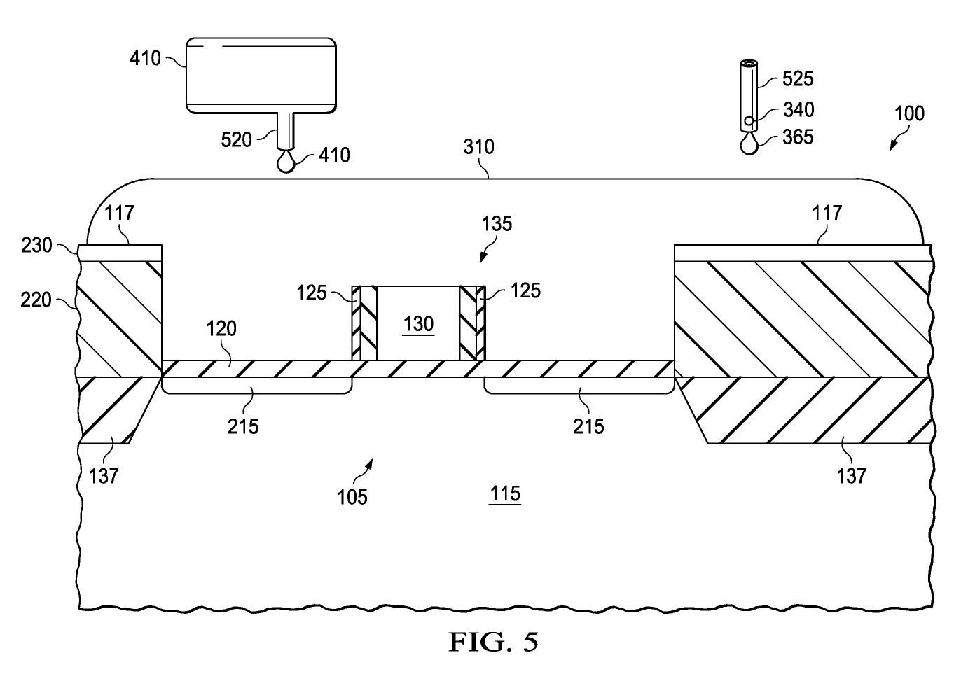

In still other cases, such as shown in FIG. 5, once again sulfuric acid and hydrogen peroxide can be mixed together to form a binary mixture 410. However, the binary mixture 410 is mixed on the surface 117 with ozone 340 dissolved in a volume of water 365. For instance first and second tubes 520, 525 can deliver a flow of the binary mixture 410 and a flow of the ozone in water 365, respectively, directly on the surface 117. Similar to the embodiment shown in FIG. 3, this embodiment has the advantage of not requiring a external heat source, because mixing binary mixture 410 and a flow of the ozone 340 in water 365 will result in an exothermic reaction and sufficient heat generation to reach the desired elevated temperature.

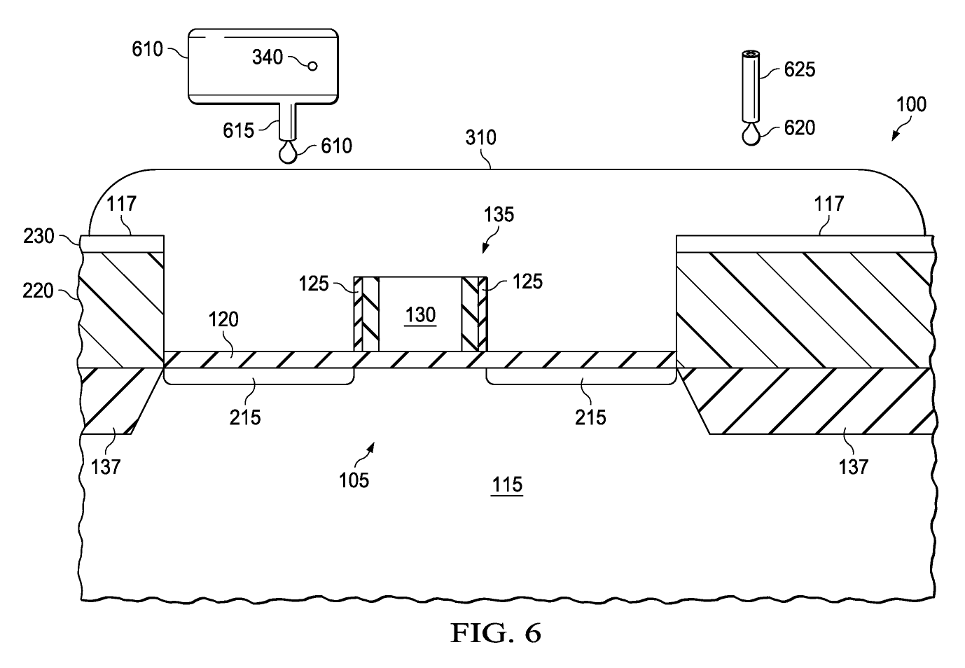

In still other cases, such as shown in FIG. 6, one sulfuric acid or hydrogen peroxide can be mixed with ozone 340 dissolved in a volume of water to form a binary mixture 610, and delivered by a first tube 615. This ozone-containing binary mixture 610 can then be mixed with the other of sulfuric acid or hydrogen peroxide 620 that is not in the binary mixture 610, and delivered by a second tube 625. As illustrated in FIG. 6, in some preferred embodiments, mixing occurs at the substrate surface 117, although in other cases, mixing can be done in a mixing chamber similar to that discussed in the context of FIG. 3. In some cases, provided that the binary mixture 610 and the other of sulfuric acid or hydrogen peroxide 620 are mixed together soon before delivery to the surface 117 (e.g., about 1 minute or less), the mixture 310 can be raised to the desired elevated temperature without the need for an external heating source.

Any conventional ozone-generating methods can be used in order to introduce ozone 340 into the mixture 310, binary mixtures 410, 610, or water 365 as a described above in the context of FIGS. 3-6. For instance, ozone can be generated by a process that includes dissociating oxygen gas in an electric field, such as achieved in a plasma tool. Or, ozone can be generated by a process that includes irradiating water with an ultraviolet wavelength of light.

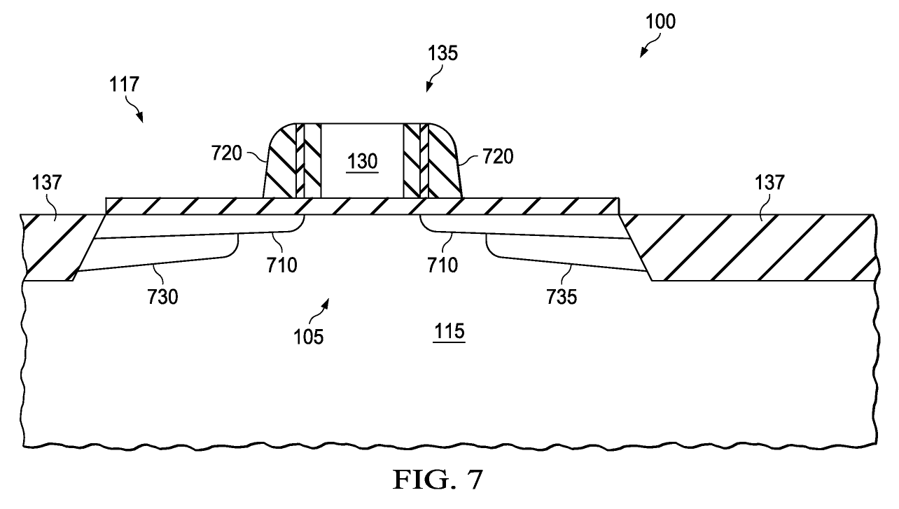

FIG. 7 shows the IC 100 after performing a number of additional procedures in the fabrication of the semiconductor device 105. For instance, a thermal anneal can be performed to diffuse the implanted dopant region 215 (FIG. 2) in the substrate 115 to form lightly doped drain (LDD) extension regions 710 adjacent to the gate structure 135. One of ordinary skill in the art would be familiar with the various conventional methods to make these structures or other structures to complete the construction of the device 105 and IC 100. In some cases additional photoresist layers can be used to guide the selective implantation of ion species into other doped regions of the substrate as part of at least some of these methods. For instance, sidewall structures 720 (e.g., silicon oxide sidewalls) can be formed on the gate structure 135, and the substrate 115 can be further implanted with additional dopant species as part of forming source and drain regions 730, 735 adjacent to the gate structure 135, while other regions and devices of the substrate are covered with another photoresist layer (not shown), and then remove the implanted photoresist using the above described procedures.

FIG. 7 illustrates another aspect of the disclosure, an IC 100. The IC 100 comprises at least one semiconductor device 105 that is made by a process that includes removing an implanted photoresist layer by the one embodiment of the processes described above in the context of FIGS. 1-7. For instance, the device 105 includes a gate structure 135 on a substrate 115 and one or more doped regions formed adjacent to the gate structure 135. In some embodiments, at least one doped region corresponds to a lightly doped drain (LDD) extension region 710, or a source 730 or drain 735 region, of the device 105 configured as a MOS transistor

At least one of the doped regions are formed by a process that includes depositing a photoresist layer 110 (FIG. 1) on the substrate 115, and, implanting one or more dopant species 210 through openings 140 in the photoresist layer 110 and into the substrate 115 and the photoresist layer 110, thereby forming an implanted photoresist layer 220 (FIG. 2). The process of forming the at least one doped region includes removing the implanted photoresist layer 220, including exposing the implanted photoresist layer 220 to a mixture 310 that includes sulfuric acid, hydrogen peroxide and ozone wherein the mixture 310 is at a temperature of at least about 130° C.

Those skilled in the art to which the invention relates will appreciate that other and further additions, deletions, substitutions and modifications may be made to the described example embodiments, without departing from the invention.

What is claimed is:

1. A method of manufacturing an integrated circuit, comprising:
fabricating a semiconductor device, including:
depositing a photoresist layer on a substrate surface;
implanting one or more dopant species through openings in said photoresist layer into said substrate, and into said photoresist layer, thereby forming an implanted photoresist layer; and
removing said implanted photoresist layer, including exposing said implanted photoresist layer to a mixture that includes sulfuric acid, hydrogen peroxide and ozone wherein said mixture is at a temperature of at least about 130° C.

2. The method of claim 1, wherein said temperature is in a range of about 150 to 200° C.

3. The method of claim 1, wherein said mixture includes said sulfuric acid as an about 98 wt % solution and said hydrogen peroxide as an about 30 wt % solution in a ratio that ranges from about 65:35 to about 85:15, and said mixture further includes said ozone in a range of about 1 to 70 ppm by weight.

4. The method of claim 1, wherein forming said mixture includes flowing about 600 ml/min of about 98 wt % said sulfuric acid solution and flowing about 200 ml/min of about 30 wt % said hydrogen peroxide solution onto said surface wherein one or both of said sulfuric acid solution or said hydrogen peroxide solution further include about 70 ppm by weight of said ozone.

5. The method of claim 1, wherein said mixture further includes water added within about 1 minute of said mixture contacting said surface.

6. The method of claim 5, wherein said mixture includes said sulfuric acid as an about 98 wt % solution and said hydrogen peroxide as an about 30 wt % solution, and said water in a ratio that ranges from about 60:20:4 to about 80:30:8, and said mixture further includes said ozone in a range of about 1 to 70 ppm by weight.

7. The method of claim 5, wherein forming said mixture includes flowing about 600 ml/min of about 98 wt % said sulfuric acid solution, flowing about 200 ml/min of about 30 wt % said hydrogen peroxide solution, and flowing about 1 to 50 ml/min ml/min of said water onto said surface wherein said water includes about 1 to 70 ppm by weight of said ozone.

8. The method of claim 1, wherein implanting said at least one dopant species includes implanting at a dose of at least about 1E12 atom/cm².

9. The method of claim 1, wherein said implanted photoresist layer includes an outer implant crust composed of a carbon-rich hydrocarbon.

10. The method of claim 9, wherein said implanted photoresist layer has a thickness in a range of about 1000 to 5000 nm, and said outer crust has a thickness in a range of about 60 to 140 nm.

11. The method of claim 1, wherein removing said implanted photoresist layer further includes:
mixing said sulfuric acid and said hydrogen peroxide together to form a binary mixture;
introducing said ozone as a gas into said binary mixture; and
heating said binary mixture with an external heat source.

12. The method of claim 1, wherein removing said implanted photoresist layer further includes simultaneously mixing together on said surface:
a volume of said sulfuric acid,
a volume of said hydrogen peroxide, and
said ozone dissolved in a volume of water.

13. The method of claim 1, wherein removing said implanted photoresist layer further includes:
mixing said sulfuric acid and said hydrogen peroxide together to form a binary mixture; and
mixing together on said surface, a flow of said binary mixture and a flow of said ozone dissolved in a volume of water.

14. The method of claim 13, wherein said flow of said ozone dissolved in a volume of water is adjusted so as to cause said temperature to be attained.

15. The method of claim 1, wherein removing said implanted photoresist layer further includes:
mixing one of said sulfuric acid or said hydrogen peroxide with said ozone dissolved in a volume of water to form a binary mixture, and
mixing together on said surface, the other of said sulfuric acid or said hydrogen peroxide with said binary mixture.

16. The method of claim 1, wherein said ozone is generated by a process that includes dissociating oxygen gas in an electric field.

17. The method of claim 1, wherein said ozone is generated by a process that includes irradiating water with an ultraviolet wavelength of light.

18. A method of manufacturing an integrated circuit, comprising:
fabricating a semiconductor device, including:
forming a gate structure on a substrate;
depositing a photoresist layer on said substrate, including said gate structure;
forming an opening in said photoresist layer so as to expose said gate structure and portions of said substrate in the vicinity of said gate structure;
implanting dopant species through said openings into said substrate, and, into said photoresist layer, thereby forming an implanted photoresist layer; and
removing said implanted photoresist layer, including exposing said implanted photoresist layer to a mixture that includes sulfuric acid, hydrogen peroxide and ozone wherein said mixture is at a temperature of at least about 130° C.

19. An integrated circuit, comprising:
one or more semiconductor devices, each of said semiconductor devices including:
a gate structure on a substrate;
one or more doped regions formed adjacent to said gate structure, wherein said at least one of said doped regions are formed by a process that includes:
depositing a photoresist layer on said substrate;
implanting one or more dopant species through openings in said photoresist layer into said substrate, and into said photoresist layer, thereby forming an implanted photoresist layer; and
removing said implanted photoresist layer, including exposing said implanted photoresist layer to a mixture that includes sulfuric acid, hydrogen peroxide and ozone wherein said mixture is at a temperature of at least about 130° C.

20. The integrated circuit of claim 17, wherein said at least one doped region corresponds to a lightly doped drain extension region, or a source or drain region, of said device configured as a MOS transistor.
